(19) United States
(12) Patent Application Publication
(10) Pub. No.: US 2025/0112174 A1
(43) Pub. Date: Apr. 3, 2025

(54) ANNEALED SHAPE MEMORY ALLOY ON A SUBSTRATE

(71) Applicant: Intel Corporation, Santa Clara, CA (US)

(72) Inventors: Siddarth KUMAR, Chandler, AZ (US); Shripad GOKHALE, Gilbert, AZ (US); Edvin CETEGEN, Chandler, AZ (US); Praneeth NAMPALLY, Chandler, AZ (US); Astitva TRIPATHI, Mesa, AZ (US); Sairam AGRAHARAM, Chandler, AZ (US)

(21) Appl. No.: 18/374,618

(22) Filed: Sep. 28, 2023

(51) Int. Cl. H01L 23/00; H01L 21/3205

(52) U.S. Cl. CPC H01L 23/562; H01L 21/32051; H01L 24/16; H01L 2224/16145

(57) ABSTRACT

Embodiments herein relate to systems, apparatuses, techniques or processes for forming an annealed shape metal alloy (SMA) on a wafer or a die complex. In embodiments, the annealed SMA, when heated above a transition temperature, may enter an Austenite phase and return to the shape that the wafer or die complex had when it was annealed. In embodiments, this may maintain a shape of a wafer or a die complex during higher temperature processing, for example during reflow, when the package undergoes fabrication. Other embodiments may be described and/or claimed.

Embodiments of the present disclosure generally relate to package assemblies, and in particular to wafers or to die complexes of a package.

### BACKGROUND

Advanced packaging solutions, for example packages that include multi-chiplets, are part of a suite of technologies that facilitate high performance computing applications. These applications include supercomputing, artificial intelligence/machine learning, data center graphics, and accelerators. As product demand for high performance computing increases, it will also lead to an increase in complexity of stack architectures and the size of the die stacks in order to meet performance and efficiency needs.

### BRIEF DESCRIPTION OF THE DRAWINGS

FIGS. 1A-1B illustrate a legacy wafer and a legacy die complex, which may include one or more dies, on a base wafer with example warpages at reflow temperatures.

FIGS. 2A-2D illustrate top view and side views of a package that includes a singulated a die complex on a base wafer, with a shape memory alloy (SMA) pattern annealed on a surface of the die complex or surfaces of the base wafer, in accordance with various embodiments.

FIGS. 3A-3D illustrate top view and side views of a package that includes a base wafer during wafer level assembly prior to singulation with a SMA pattern annealed on the surface of the die complexes or surfaces of the base wafer, in accordance with various embodiments.

FIG. 4 illustrates a top view of various SMA patterns that may be annealed on a surface of the die complex or on a surface of a base wafer, in accordance with various embodiments.

FIG. 5 illustrates a diagram of a wafer with an SMA pattern as the SMA pattern moves into an Austenite phase, in accordance with various embodiments.

FIG. 6 illustrates a perspective view of a laser annealing a SMA pattern on a surface of a wafer, in accordance with various embodiments.

FIGS. 7A-7B illustrate perspective views of a warping simulation of a die complex with and without an annealed SMA pattern on a surface of the die complex, in accordance with various embodiments.

FIGS. 8A-8C illustrate perspective views and side views of a package that includes an annealed SMA pattern on dies, substrate, and/or molding, in accordance with various embodiments.

FIG. 9 illustrates a process flow for annealing a SMA onto a surface of a base wafer to control warpage at manufacturing stages beyond a carrier wafer bond/through silicon via (TSV) reveal stage, in accordance with various embodiments.

FIG. 10 illustrates a process flow for annealing a SMA onto a surface of a die complex to control warpage for thermo-compression bonding (TCB), in accordance with various embodiments.

FIG. 11 illustrates an example of a process for forming an annealed SMA pattern on a surface of a base wafer, in accordance with various embodiments.

FIG. 12 schematically illustrates a computing device, in accordance with embodiments.

### DETAILED DESCRIPTION

Embodiments of the present disclosure may generally relate to systems, apparatus, techniques, and/or processes directed to using an annealed SMA, which may be referred to as an annealed SMA pattern, in conjunction with a semiconductor package. In embodiments, the annealed SMA may be used on a surface of a die complex or on a surface of a base wafer in the package. In embodiments, the annealed SMA facilitates maintaining a shape of a wafer or a die complex during chip attach or wafer level assembly processing while the package is being fabricated.

Stages during manufacturing may involve higher temperatures that may cause a legacy wafer or die complex to warp beyond processing tolerances. For example, the higher temperature processing may include a reflow process, a thermal-compression bonding (TCB) process, a direct bonding process, and/or a hybrid bonding process. In embodiments, the SMA may be placed on a wafer or on a die complex, and then annealed prior to singulation. In other embodiments, the SMA may be placed and then subsequently annealed on any layer that may be in the package. In embodiments, the SMA may include a nickel and titanium alloy (Nitinol). In embodiments, the annealed SMA on the surface of the die complex or the wafer may be patterned in a design to reduce warpage during high temperature stages of the manufacturing process.

A characteristic of an annealed SMA is that it has two solid-state phases: a low-temperature Martensite phase were the annealed SMA may be deformed, and a high-temperature Austenite phase where the annealed SMA returns to its set shape. The transition between the two phases occurs at a specific phase transition temperature, which depends upon the SMA compositions and concentrations of its various alloys.

An SMA gets its set shape by annealing and SMA at a high temperature, for example using a laser. In embodiments, this set shape may be acquired by annealing the SMA when a wafer or a die complex is flat. For example, the annealing temperature for the SMA Nitinol is around 500° C. After annealing, the SMA will acquire a phase transition temperature. Below the phase transition temperature, annealed SMA will be in a Martensite phase, where die complex or the wafer and the annealed SMA may be deformed elastically or plastically.

However, when heated above its phase transition temperature, the SMA will transition to an Austenite phase and the annealed SMA will revert to its original set shape defined during annealing. Thus, a die complex or wafer that has a surface with an annealed SMA that has a set shape when the substrate was flat, will tend to flatten out as higher temperature processes of package fabrication exceed the phase transition temperature. This will cause the annealed SMA on the die complex or wafer to go into the Austenite phase and return to its set shape when annealed. This higher temperature may occur during the reflow process.

As a result, in embodiments, the resulting flat wafer and/or die complex during reflow will be able to form a higher quality electrical and physical bond with a flat component to which the die complex or wafer is to couple. In embodiments, the placement of the SMA and subsequent annealing of an SMA pattern may occur at any stage within the manufacturing process. For example, it may occur initially during the wafer formation, or it may occur at other times in the manufacturing process, for example after a TSV reveal stage.

In legacy implementations, large complex multi-chiplet and wafer stacks also have high wafer and die warpage during manufacture, making them difficult to assemble as the package is formed due to warpage that creates process and tool limitations. For example, in legacy implementations, there is no manufacturable chip attach process window for large die or wafer complexes, for example die complexes greater than two times the maximum reticle size. This is due to high warpage at reflow temperatures due to large substrate-stack die complex coefficient of thermal expansion (CTE) mismatches. Options to mitigate warpage concerns, include restrictive product design rules, for example restricting die complex size and thickness, bump pitch and critical dimensions such as molds shelf size, and design attributes such as TSV density.

In addition, legacy assembly process tools are not able to reliably handle warped wafers during TSV reveal, bumping or metallization during package side metal and/or package side bump processes due to the wafer stacks not meeting process warpage specifications. Legacy implementations for a less than two-times reticle size die may include attempts to optimize chip attach process parameters including temperature and force, tightening substrate supplier specifications such as bump coplanarity. Legacy attempts may also include making package architecture changes, for example changing bump critical dimensions and pitch, splitting solder between a die in the substrate, and/or restricting TSV density.

Although these legacy attempts may provide some improvements in package yield and may enable a manufacturable process window, there are disadvantages. For example, addressing warpage issues by TCB process changes in legacy systems limits the manufacturing process window and increases yield loss. In addition, these legacy implementations are not scalable. For example, there is no manufacturable process window beyond a two-times reticle die or die complex size. In addition, tightening supplier specifications limits package yield and increases cost. In addition, package architecture changes such as implementing reduced die stack thickness or size limitations, bump pitch and critical dimension changes, or TSV density restrictions limit product competitiveness and design options. Therefore, embodiments of an annealed SMA on a wafer or a die complex may address some of these legacy issues.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

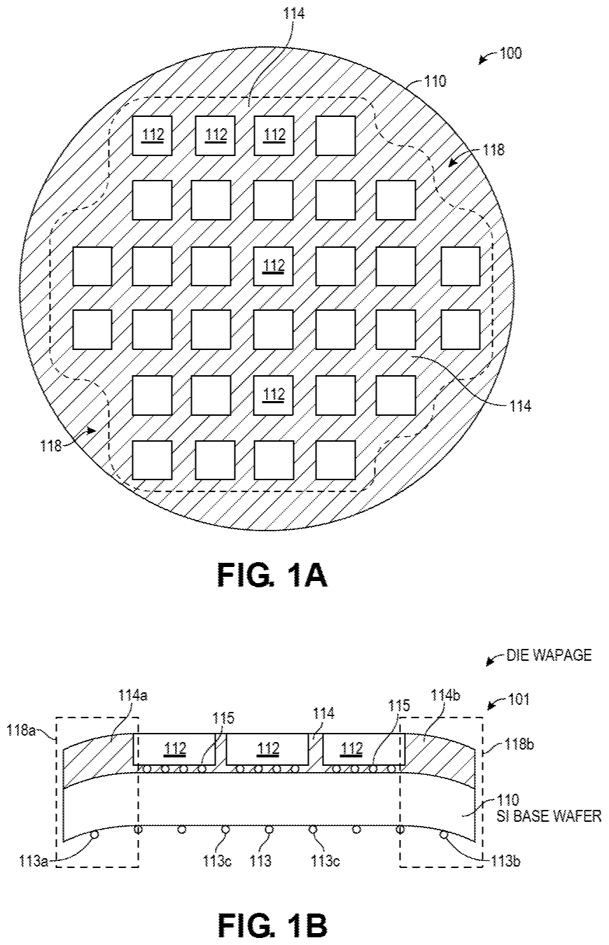

FIGS. 1A-1B illustrate a legacy wafer and a legacy die complex on a base wafer with example warpages at reflow temperatures. Legacy package 100 shows a top-down view that includes a base wafer 110 onto which a plurality of dies 112 are placed. The dies 112 may be referred to as chip or chiplets. A mold compound 114, which may be an organic compound, is placed on the surface of the base wafer 110 and around the dies 112. In this legacy implementation, the legacy package 100 may be heated during the reflow process to a temperature on the order of 250° C. As a result of this heating, the base wafer 110 may be subject to warping, which may be due to different coefficients of thermal expansion (CTE) of different materials within the base wafer 110 or with the mold compound 114 on the wafer.

In addition, the overall CTE of the dies 112 may also affect warping of the base wafer 110, for example if the overall CTE of the dies 112 that is different than the base wafer 110. In other examples, the dies 112 may have a CTE that is similar to the base wafer 110, therefore partially reducing the warping of the base wafer 110 proximate to the dies 112. As a result, areas 118 near the edges of the legacy package 100 may be particularly susceptible to warping and distortion during higher temperatures during reflow.

Legacy package 101 of FIG. 1B shows a cross-section side view of legacy package 100. Dies 112 may be attached to the base wafer 110 through solder balls 115. In other legacy implementations, the dies 112 may be coupled using direct bonding or hybrid bonding. In embodiments, solder balls 113 may be at a bottom of the base wafer 110, and be used to connect the legacy package 101 to some other substrate, such as a printed circuit board (PCB) (not shown) or to some other surface.

At the reflow temperatures, a CTE difference between the mold compound 114a and the base wafer 110 may cause a downward deflection in the legacy package 101 proximate to the area 118a at a first edge of the package. Similarly, the CTE difference in the molding compound 114b and the base wafer 110 may cause a downward deflection proximate to the area 118b at a second edge of the package. As a result, a subset of the solder balls 113c that may be in a first plane at the bottom of the base wafer 110 will be in a different plane than either the solder balls 113a within the area 118a or the solder balls 113b within the area 118b.

As a result, the bottom surface of the base wafer 110 will not be planar, and therefore will not be able to robustly electrically couple with or physically attach to another flat surface component (not shown). Although legacy packages 100, 101 shows dies 112 on a base wafer 110, the warping described above may also occur in wafers of various sizes, including large reticle sizes, substrates within stacked dies such as dies 112 or other components (not shown), layers within any other component (not shown) within a package, or layers that may be within any other physical device or apparatus.

In legacy implementations, this warpage may occur both at the wafer-level assembly as well as at an attach of a singulated die onto a substrate. In addition, as package configurations become more complicated, controlling margins during the manufacturing process also becomes more difficult. Given different package configurations, or stack ups, patterns of warping may become quite complex. In particular, post-singulation, when a very large but very thin die complex needs to be attached to a substrate, it must be taken to reflow temperatures to attach to the substrate. The resulting warpage may result in the inability to form a high-quality connection. In addition, as the wafer and/or die complex goes through various manufacturing stages, each tool with respect to that manufacturing stage has a particular capability in terms of handling warpage within a certain range. This is particularly true during the TSV reveal stage or other stages when the wafer or die complex do not meet process specifications. Warpage exceeding a specified range will substantially reduce yields.

Thus, in the embodiments described herein, and more particularly below, the techniques described that may reduce warpage of wafers and/or die complexes, and may be applied broadly to layers of any physical device or apparatus.

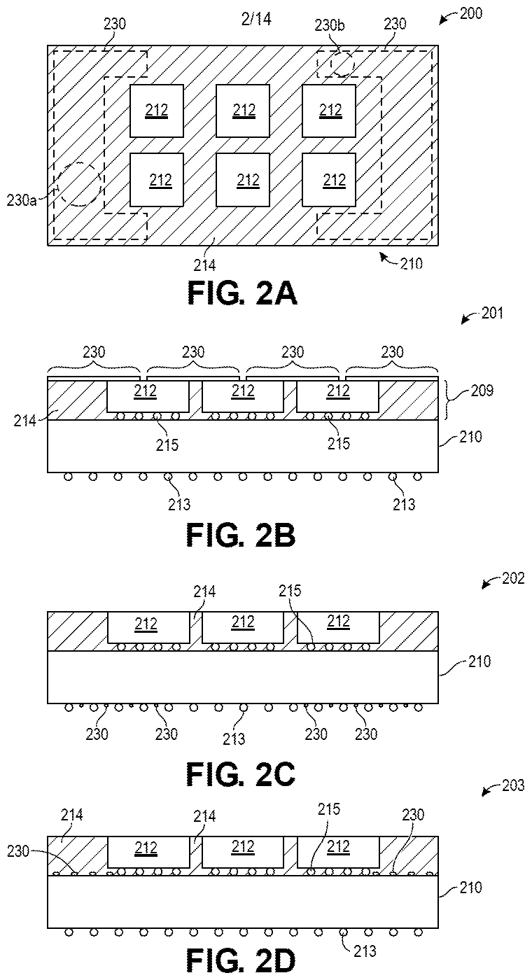

FIGS. 2A-2D illustrate top view and side views of a package that includes a singulated a die complex on a base wafer, with a SMA pattern annealed on a surface of the die complex or surfaces of the base wafer, in accordance with various embodiments. FIG. 2A shows a top-down view of package 200 that includes a base wafer 210, which may be a silicon wafer, onto which a plurality of dies 212 are placed. Mold compound 214 may be placed on the surface of the base wafer 210 and around the dies 112. Package 200, base wafer 210, dies 212, and mold compound 214 may be similar to legacy package 100, base wafer 110, dies 112, and mold compound 114 of FIGS. 1A-1B.

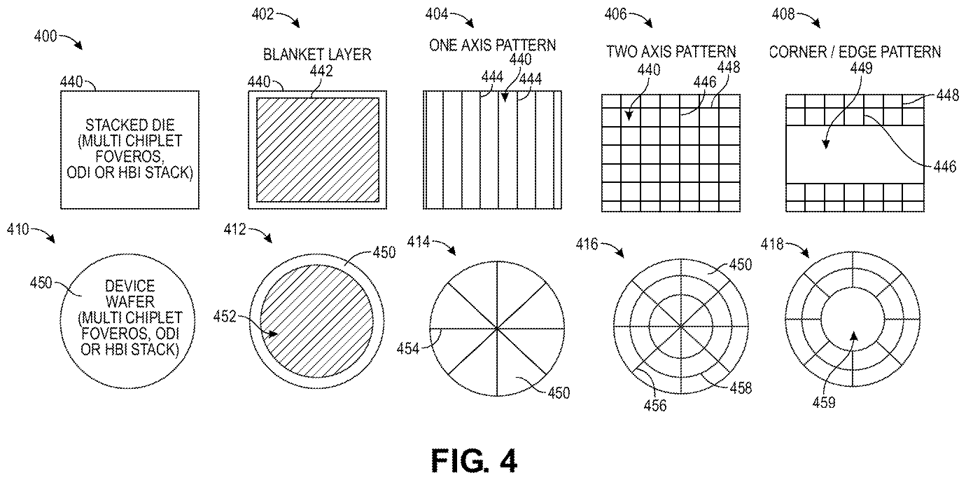

An SMA pattern 230 may be placed on a surface of the base wafer 210. The SMA pattern 230 on the base wafer 210 may be different in different regions of the base wafer 210. For example the pattern in region 230a may be different than the pattern in a region 230b due to the proximity to one of the dies 212. In embodiments, the SMA pattern 230 may be in the form of squares, which may be referred to as a two-axis pattern. Other example embodiments of an SMA pattern 230 are described further below with respect to FIG. 4.

In embodiments, the SMA pattern 230 may include alloys such as nickel and titanium (Nitinol). Other alloys may include: copper, aluminum, and nickel; iron, manganese and silicon; copper, zinc, and aluminum; silver and cadmium; gold and cadmium; copper, aluminum, and nickel; copper and tin; copper and zinc; indium and titanium; nickel and aluminum; iron and platinum; and/or manganese and copper.

In embodiments, the SMA has unique material properties due to its two solid-state phases, the high-temperature Austenite phase (E: ˜75-83 GPa for Nitinol) and a low temperature Martensite phase (E: 28-40 GPa for Nitinol). The transition between the phases occurs at a specific activation temperature, or a transition temperature, which is SMA specific. For Nitinol, the activation temperature may typically range from −20° C. to 130° C. depending upon the nickel and titanium composition within the SMA.

An SMA has a unique property where its shape can be “set” through annealing the SMA at high temperatures, typically ˜500° C. for Nitinol alloys. When cooled to room temperature, or to a temperature below the phase transition temperature, the SMA changes from high temperature Austenite phase to low temperature Martensite phase and can be deformed elastically or plastically just as any other metal alloy.

After deformation, if the SMA is heated above its phase transition temperature, the SMA transitions to Austenite phase and reverts to the original set shape it had at annealing. This unique property of an SMA of reverting back to an original set shape at the phase transition temperature may be used to control wafer and/or die complex warpage.

In FIG. 2B, package 201 shows a cross-section side view of a package that may be similar to package 200, with dies 212 connected with the base wafer 210 using solder balls 215, and with the solder balls 213 at a bottom surface of the base wafer 210. The solder balls 215 and the solder balls 213 may be similar to solder balls 115 and solder balls 113 of FIG. 1B.

As shown, the SMA pattern 230 is at a top surface of the die complex 209 that includes dies 212 and mold compound 214. In embodiments, the SMA pattern 230 may be on top of, or may be partially on top of the dies 212. In embodiments, the SMA pattern 230 may extend to the edges of the package 201. In embodiments, the SMA pattern 230 may be initially applied by placing an SMA material on the die complex 209 using a sputtering technique. In embodiments, a thickness of the SMA material may range from 1 μm to 10 μm, or in other embodiments may be greater than 10 μm depending upon the architecture of the die complex 209 and the composition of the base wafer 210. In some embodiments, the thickness of the SMA material may be uniform across the die complex 209. In some embodiments, the thickness of the SMA material may vary.

Subsequently, after placing the SMA material, an annealing process may be used to anneal portions of the SMA material to form, or to “set,” the SMA pattern 230. In embodiments, the SMA pattern 230 may include annealed SMA material that has both a Martensite phase and an Austenite phase as discussed further below.

In FIG. 2C, package 202 shows a cross-section side view of a package that may be similar to package 200, with dies 212 connected with the base wafer 210 using solder balls 215, and was solder balls 213 at a bottom surface of the base wafer 210.

As shown, the SMA pattern 230 is at the bottom surface of the base wafer 210. In embodiments, the SMA pattern 230 may be at least partially between solder balls 213. In embodiments, the SMA pattern 230 may be initially applied by placing an SMA material on the bottom surface of the base wafer 210 using a sputtering technique. In embodiments, a thickness of the SMA material may range from 1 μm to 10 μm, or in other embodiments may be greater than 10 μm, depending upon the design/architecture of the die stack on the base wafer 210 and the height of the solder balls 213.

In FIG. 2D, package 203 shows a cross-section side view of a package similar to package 200, with dies 212 connected with the base wafer 210 using solder balls 215, and with the solder balls 213 at a bottom surface of the base wafer 210. As shown, SMA pattern 230 is on a top of the base wafer 210 between the mold compound 214 and the base wafer 210. In embodiments, the SMA pattern 230 may also be at least partially under a die 212 (not shown).

With respect to FIGS. 2A-2D, it should be appreciated that the design of the SMA pattern 230 may be tailored to a particular stack configuration on the base wafer 210, and may be designed to reduce warpage, counter CTE expansion, and to flatten local convex or concave shapes in the base wafer 210 during high process temperature manufacturing stages such as during chip attach and surface mount technology (SMT) manufacturing stages.

In embodiments, larger multi-chiplet stack complexes within packages may be manufactured that were not able to be manufactured before. As a result, design rules for die stack sizes, bump pitch and critical dimensions, mold shelving, and TSV density may be expanded by minimizing warpage of wafers during assembly, as well as reducing die warpage with respect to solder bridging after chip attach. In addition, in embodiments, by customizing SMA pattern 230 for each stack and a complex stack architecture, very different architectures may as a result have a similar high-temperature warpage profile, thus enabling reuse of the same chip attach processes and hardware, reducing yield loss and leading to cost savings.

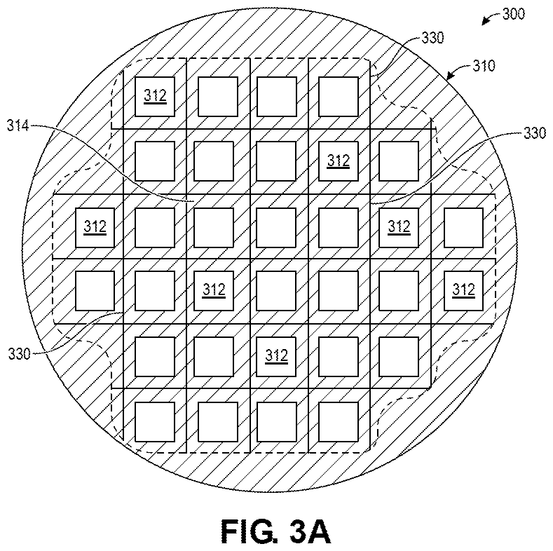

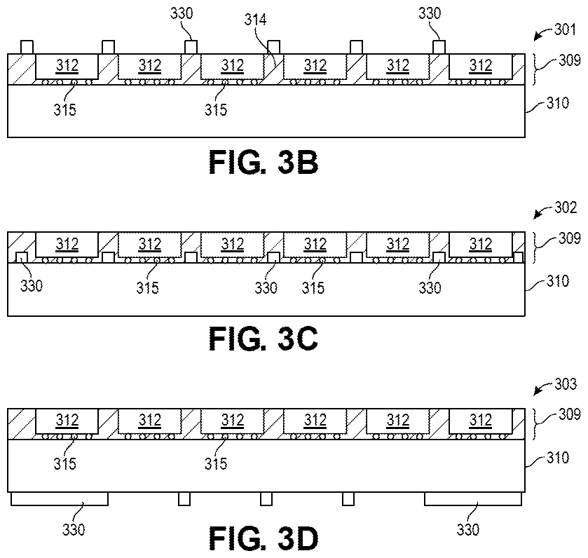

FIGS. 3A-3D illustrate top view and side views of a package that includes a base wafer during wafer level assembly prior to singulation with a SMA pattern annealed on the surface of the die complexes or surfaces of the base wafer, in accordance with various embodiments. FIG. 3A shows a top-down view of package 300 that includes a base wafer 310, which may be a silicon base wafer, onto which a plurality of dies 312 are placed. Mold compound 314 may be placed on the surface of the base wafer 310 and at least partially around the dies 112. Package 300, base wafer 310, dies 312, and mold compound 314 may be similar to package 200, base wafer 210, dies 212, and mold compound 214 of FIG. 2A. The dies 312 and the mold compound 314 may together form a die complex 309, which may be seen in FIG. 3B.

In embodiments, an SMA pattern 330 may be placed on the dies 312 and/or the mold compound 314 as shown. The SMA pattern 330 is a simple pattern that surrounds at least part of each of the dies 312, and also extends toward and edge of the wafer 310. In embodiments, the SMA pattern 330 represents an annealed layer of SMA material.

In FIG. 3B, package 301 shows a cross-section side view of a package that may be similar to package 300, with dies 312 connected with the wafer 310 using solder balls 315. Solder balls 315 may be similar to solder balls 215 of FIG. 2B. As shown, the SMA pattern 330 may be at the top surface of the die complex 309, as shown as being placed between the dies 312. Other embodiments may include the SMA pattern 330 partially or completely overlapping one or more of the dies 312. The pattern and dimensions of the SMA pattern 330 may depend upon the architecture/layout of the dies 312 and the mold compound 314.

In FIG. 3C, package 302 shows a cross-section side view of a different embodiment of package 300, where the SMA pattern 330 was placed on the top of the base wafer 310 before the die complex 309 was placed on the base wafer 310. In these embodiments, the SMA pattern 330 may be positioned such that it does not interfere with the connection of the solder balls 315 with the base wafer 310.

In FIG. 3D, package 303 shows a cross-section side view of a different embodiment of package 300, where SMA pattern 330 may be placed at a bottom of the base wafer 310. In embodiments, the SMA pattern 330 may be placed either before or subsequent to the placement of the die complex 309 on the base wafer 310.

FIG. 4 illustrates a top view of various SMA patterns that may be annealed on a surface of the die complex or on a surface of a base wafer, in accordance with various embodiments.

The various patterns of the SMA are examples only of how an SMA may be distributed in a pattern, and are not intended to limit the embodiments of the patterns of the SMA that may be applied to a surface of a material. Diagram 400 shows a top-down view of a die complex 440, which may be similar to die complex 209 of FIG. 2A. The die complex 440 may be a part of a package, which may be a portion of a multi-chiplet Foveros™ implementation, an omnidirectional interconnect (ODI™), or a high bandwidth interconnect (HBI) stack.

Diagram 402 shows an example embodiment where an SMA pattern 442 has been placed on a surface of the die complex 440. In embodiments, the SMA pattern 442 has a solid shape pattern, that may be a square shape and that may substantially cover the surface of the die complex 440. In embodiments, the SMA pattern 442 may be annealed either using laser, or by using some other heating process to heat the SMA pattern 442 above its set point.

Diagram 404 shows an example embodiment where a surface of the die complex 440 includes a one-axis pattern of SMA pattern 444 that runs in a vertical direction. Diagram 406 shows an example embodiment where a surface of the die complex 440 includes a two-axis SMA pattern 446, 448 that cross each other. As shown, the SMA pattern 446, 448 cross each other orthogonally, where in other embodiments the SMA pattern 446, 448 may intersect each other at angles other than 90°.

Diagram 408 shows an example embodiment where a surface of the die complex 440 includes an edge pattern using SMA pattern that may be similar to SMA pattern 446, 448, however with a void of SMA pattern 449 near the center of the die complex 440. In this embodiment, the void of SMA pattern 449 may be selected due to other components, such as dies 212 of FIG. 2A that may be on or near the region and will reinforce the die complex 440 and result in less warpage during high temperature stages of the manufacturing process. It should also be appreciated that each of these embodiment examples may have irregular shapes, irregular thicknesses, and in some embodiments have different percentage compositions for the SMA pattern that are placed on the die complex 440.

Diagram 410 shows a wafer 450, which may be similar to base wafer 310 of FIG. 2A. Wafer 450 may be a circular device wafer that may be subsequently singulated as a part of the manufacturing process. In embodiments, portions of the wafer 450 may be a part of a stacked die, which may be a portion of a multi-chiplet Foveros™ implementation, an omnidirectional interconnect (ODI™), or a high bandwidth interconnect (HBI) stack.

Diagram 412 shows an example embodiment where a surface of the wafer 450 includes SMA pattern 452 in a circular shape that may substantially cover the wafer 450. Diagram 414 shows an example embodiment where a surface of the wafer 450 includes a one-axis SMA pattern 454 that extends in a radial patterned direction from a center of the wafer 450. Diagram 416 shows an example embodiment where a surface of the wafer 450 includes a two-axis SMA pattern 456, 458, where one extends in a radial direction similar to SMA pattern 454, and the other includes a concentric or a concentric ring pattern away from a center of the wafer 450.

Diagram 418 shows an example embodiment where a surface of the wafer 450 includes a pattern similar to diagram 416, but with a center region 459 that does not include any SMA pattern. In this embodiment, the lack of SMA pattern at the center region 459 may be selected due to other components, such as dies 312 of FIG. 3A that may be on or near the region and will reinforce the wafer 450 and result in less warpage during high temperature stages of the manufacturing process. Again, it should also be appreciated that each of these embodiment examples may have irregular shapes, irregular thicknesses, and in some embodiments have different percentage compositions for the SMA pattern that are placed on the wafer 450.

In embodiments, the SMA patterns shown in diagram 400, 402, 404, 406, 408, 410, 412, 414, 416, 418 may be set shapes that have been annealed at a high temperature in order to set the shape of the SMA pattern while the die complex 440 and the wafer 450 may be flat or substantially flat. This facilitates the maintained flatness of die complex 440 and the wafer 450 as they are heated to a reflow temperature that will cause the SMA pattern to enter an Austenite phase, reenter their set shape, and as a result flatten the die complex 440 and the wafer 450. Also, it should be appreciated that the die complex 440 and the wafer 450 may be formed into a different shape, such as a bowl shape or some other non-planar shape, prior to the set shapes being formed in the SMA pattern. In this case, at higher temperatures when the SMA pattern enters an Austenite phase, the die complex 440 and the wafer 450 may return to their original non-planar shape.

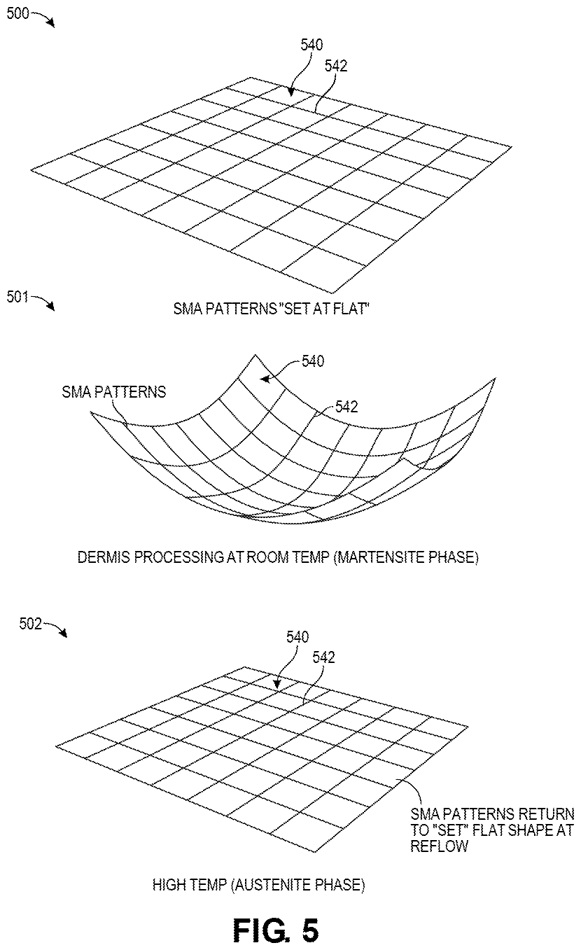

FIG. 5 illustrates a diagram of a wafer with an SMA pattern as the SMA pattern moves into an Austenite phase, in accordance with various embodiments. Diagram 500 shows wafer 540, which may be similar to base wafer 210 of FIG. 2B, that includes SMA pattern 542, which may be similar to the SMA pattern shown in diagram 406 of FIG. 4. The SMA pattern 542 have been annealed while the wafer 540 is in a flat, or planar, orientation. This may be referred to as setting the SMA pattern 542. Note that although the SMA pattern 542 is shown as a grid pattern, other patterns may be selected based upon the various embodiments (not shown) that may be placed on the wafer 540.

Diagram 501 shows wafer 540, along with SMA pattern 542 that has been warped during processing. This warpage may be due to various stages in the manufacturing process that may include via drilling, creation of cavities within the wafer 540 (not shown), or attaching other components (not shown) onto a surface of the wafer 540. Note that the stages in the manufacturing process may happen below the transition temperature at which the alloy that forms the SMA pattern 542 is in a Martensite phase, causing the SMA pattern 542 to bend or deform with the wafer 540.

Diagram 502 shows the wafer 540 and the SMA pattern 542 after the wafer reaches the temperature above the transition temperature for the alloy in the SMA pattern 542. Above this temperature, the SMA pattern 542 enters an Austenite phase during which the SMA pattern 542 returns substantially to its set shape as shown in diagram 500. In embodiments, the alloy and the SMA pattern 542 may be constructed such that the transition temperature is close to the reflow temperature for either coupling a die onto the wafer 540 using a reflow process, or for coupling the wafer 540 to some other surface such as a PCB (not shown) using a reflow process. One example of this would be during a chip attach process.

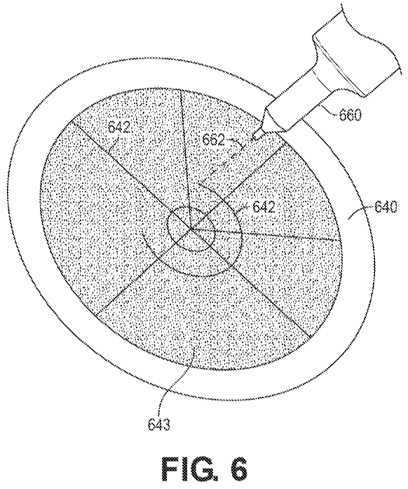

FIG. 6 illustrates a perspective view of a laser annealing a SMA pattern on a surface of a wafer, in accordance with various embodiments. Wafer 640, which may be similar to wafer 450 of FIG. 4, may be at least partially covered with an SMA layer 643 on a surface of the wafer 640. In embodiments, a laser 660 may be used to anneal portions of the SMA layer 643 to create SMA pattern 642, which may be similar to SMA pattern 454 of FIG. 4.

In embodiments, a beam of light 662 may emanate from the laser 660 and be focused onto one or more locations on the wafer 640 that include the SMA layer 643. A beam of light 662 may be focused such that a large amount of heat is applied to the location of the SMA layer 643 to anneal that location of the SMA layer 643. In embodiments, the annealing process raises the temperature of that location of the SMA layer 643 to above a set point temperature where the alloy at that location will form an Austenite phase and a Martensite phase. In embodiments, the totality of the locations of the SMA layer 643 that are annealed may form the SMA pattern 642.

In embodiments, the wafer 640 may be flat, such that when the temperature of the wafer 640, and the temperature of the SMA pattern 642, exceeds the transition temperature, the SMA pattern 642 will enter in the Austenite phase and will return substantially to the shape it had prior to annealing, e.g. will return to a flat shape. In other embodiments, the wafer 640 may not initially start out as flat, but may have some other shape. In these embodiments, at the Austenite phase, the SMA pattern 642 will attempt to return the shape of the SMA pattern 642 and the wafer 640 to their initial shape.

In embodiments, the wafer 640 may be subsequently singulated (not shown), with each singulated substrate still including a portion of the SMA pattern 642, which will attempt to return the singulated substrate to a flat shape when it is exposed to the transition temperature. In embodiments, the laser 660 may be fixed and/or the wafer 640 may be moved, where in other embodiments the laser 660 may move and/or the wafer 640 may be fixed.

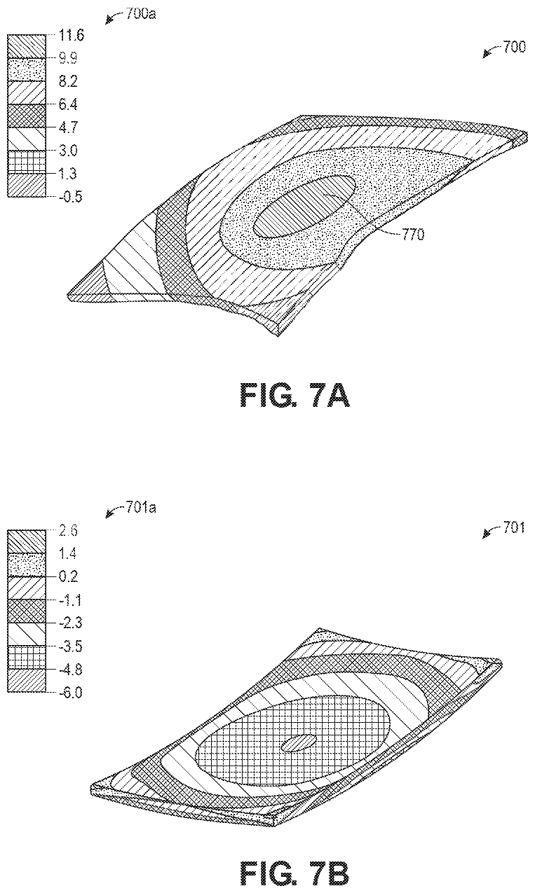

FIGS. 7A-7B illustrate perspective views of a warping simulation of a die complex with and without an annealed SMA pattern on a surface of the die complex, in accordance with various embodiments. FIG. 7A, which may be similar to FIG. 2A, shows an example of warpage of a legacy die complex that has no annealed SMA. Die complex 700 shows an overall deformation as measured between the highest and the lowest areas on a surface of the die complex 700 during reflow temperatures. Diagram 700a shows pattern map of various warpage deformation profiles.

For example, the area 770, may have a die (not shown, but may be similar to die 212 of FIG. 2B) attached at that location, and surrounded by a mold compound (not shown, but may be similar to mold compound 214 of FIG. 2B). As a result of the warpage, if the die complex 700 is coupled to another substrate or to a flat surface of another component (not shown), the lower right joint may be squeezed, and the joint under the area 770 may be open. Diagram 700a shows pattern map of various deformation profiles in micrometers.

In contrast, FIG. 7B shows an example of a die complex 701, which may be similar to die complex 700 of FIG. 7A. Die complex 701 has an SMA pattern (not shown, but may be similar to SMA pattern of diagram 406 of FIG. 4) on a backside of the die complex 701 that was supplied and annealed on the die complex 701 was flat, prior to any processing.

As a result, the overall deformation is 8.6 μm during reflow temperatures. Diagram 701a shows pattern map of various deformation distances in micrometers. In embodiments, the transition temperature of the SMA pattern associated with die complex 701 is below the reflow temperature, thus the alloy in the SMA pattern transitions to an Austenite phase where the SMA pattern attempts to return die complex 701 to its original flat configuration.

In the die complex 700 of FIG. 7A, without the SMA layer, note the portion of the die complex 700 with corners bending significantly down as compared to the die complex 701 of FIG. 7B, where the corner bending is able to be mitigated, and as a result the die complex 701 is significantly flatter, in other words it has a lower warpage.

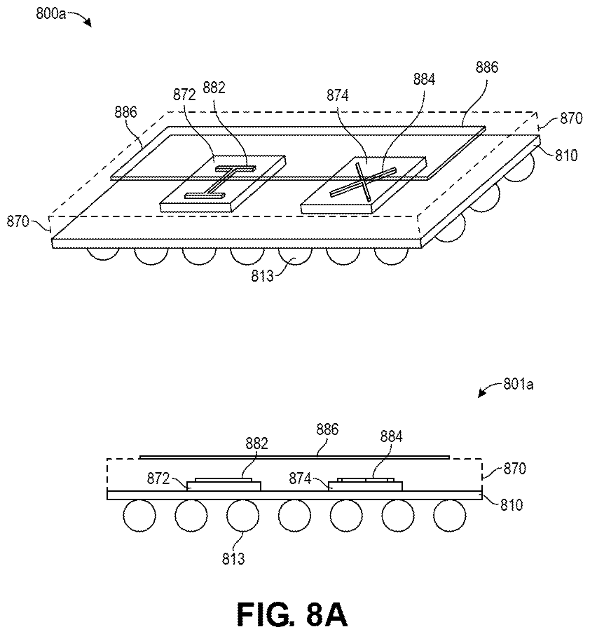

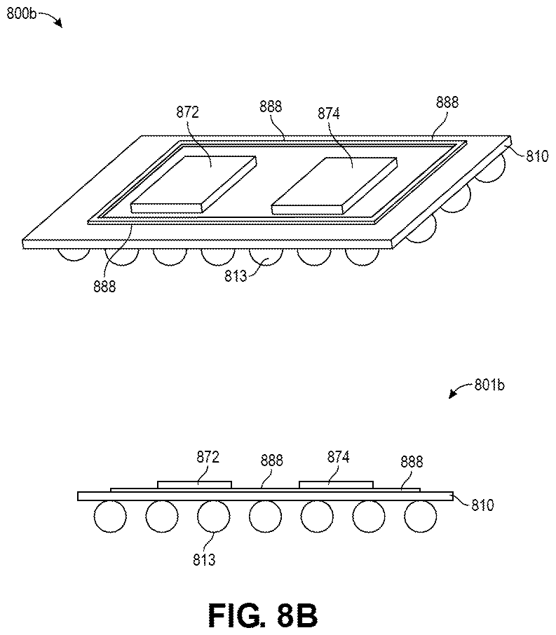

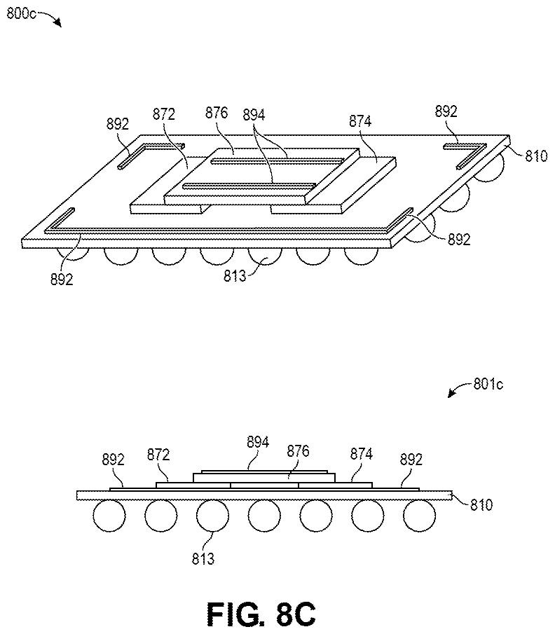

FIGS. 8A-8C illustrate perspective views and side views of a package that includes an annealed SMA pattern on dies, substrate, and/or molding, in accordance with various embodiments. FIG. 8A shows package 800a that is a perspective view that includes a substrate 810 with solder balls 813 attached to the bottom of the substrate 810 and dies 872, 874 attached on top of the substrate 810. In embodiments, a mold compound 870 may be placed on the top of the substrate 810, and at least partially surround the dies 872, 874.

In embodiments, a SMA 882 may be annealed on top of the die 872, in a “I” shape, and an SMA 884 may be placed on top of the die 874 in a “X” shape. In embodiments, the location, density, and shape of the SMA 882, 884 may be determined based upon warpage characteristics, respectively, of the dies 872, 874.

In embodiments, an SMA 886 may be placed on top of the mold compound 870. In embodiments, the SMA 886 may be proximate to, and may extend over the dies 872, 874, depending upon warpage characteristics of the package 800a. In embodiments, the SMA 882, 884, 886 may be similar to SMA 230 of FIGS. 2A-2D, or of SMA 330 of FIGS. 3A-3D. Package 801a is a side view of package 800a.

FIG. 8B shows package 800b that is a perspective view that includes substrate 810 with solder balls 813 attached to the bottom of the substrate 810, and dies 872, 874 attached on the top of the substrate 810. In embodiments, an SMA 888 may be annealed on top of the substrate 810. In embodiments, the location, density, and shape of the SMA 888 may be determined based upon warpage characteristics of the package 800b and/or the substrate 810. In embodiments, the SMA 888 may be similar to the SMA 882, 884, 886 of FIG. 8A. Package 801b is a side view of package 800b.

FIG. 8C shows package 800c that is a perspective view that includes substrate 810 with solder balls 813 attached to the bottom of substrate 810, and dies 872, 874 attached on the top of the substrate 810. In addition, a top die 876 may be on top of the dies 872, 874. In embodiments, an SMA 892 may be annealed on to the top of the substrate 810, and then SMA 894 may be annealed on top of the top die 876.

In embodiments, the location, density, and shape of the SMA 892 may be determined based upon warpage characteristics of the substrate 810, and the location, density, and shape of the SMA 894 may be determined based upon warpage characteristics of the top die 876, as well as warpage characteristics of the dies 872, 874. In embodiments, the SMA 892, 894 may be similar to SMA 882, 884, 886 of FIG. 8A. Package 801c is a side view of package 800c.

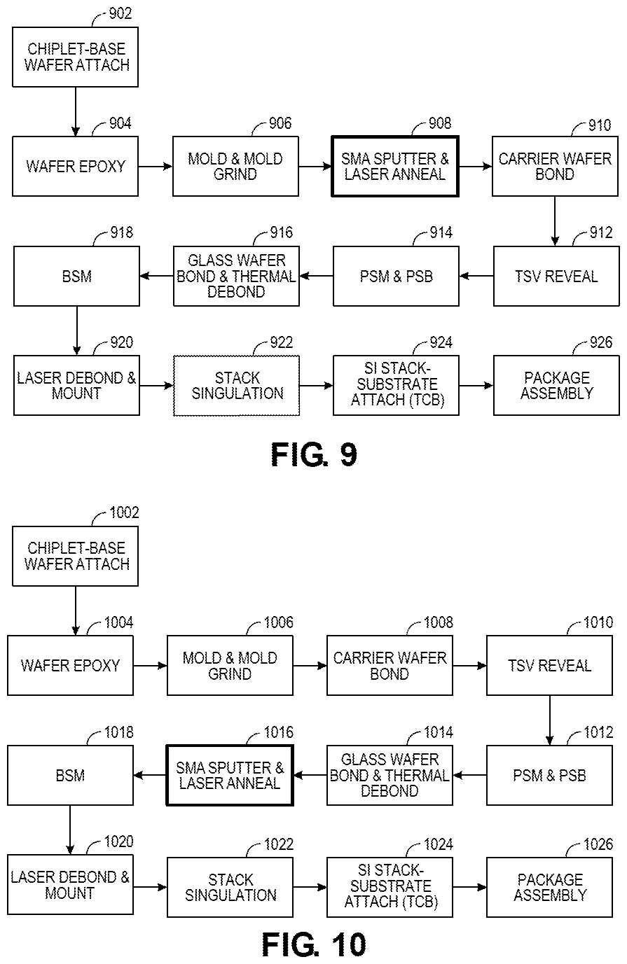

FIG. 9 illustrates a process flow for annealing a SMA onto the backside of the base wafer to control warpage at manufacturing stages beyond a carrier wafer bond/through silicon via (TSV) reveal stage, in accordance with various embodiments. In embodiments, the base wafer may also be referred to as a device wafer. Note that the manufacturing stages at block 910 and later that may involve high temperature processing will include annealed SMA on the wafer to mitigate warpage at these high temperatures.

At block 902, the process may include performing a chiplet to base wafer attach. At block 904, the process may further include performing a wafer epoxy process. At block 906, the process may further include applying a mold compound and grinding the mold compound.

At block 908, the process may further include applying SMA layer to the backside of the wafer, and then annealing all or part of the applied SMA. In embodiments, the SMA may be applied using a sputtering technique. At block 910, the process may further include bonding the device wafer to a carrier wafer. At block 912, the process may include performing a TSV reveal. At block 914, the process may include applying package side metallization and bumps. At block 916, the process may further include bonding another carrier wafer which may be a glass wafer, and performing a de-bond. At block 918, the process may further include performing a backside metal process (BSM).

At block 920, the process may further include performing a de-bond, and mounting. At block 922, the process may further include performing a stack singulation, for example by sawing. At block 924, the resulting singulated stacks may be attached to a substrate, for example through thermo-compression bonding (TCB). At block 926, the process may further include performing the final package assembly.

FIG. 10 illustrates a process flow for annealing a SMA warpage for thermo-compression bonding (TCB), in accordance with various embodiments. At block 1002, the process may include performing a chiplet to base wafer attach. At block 1004, the process may further include performing a wafer epoxy process. At block 1006, the process may further include applying a mold compound and grinding the mold compound.

At block 1008, the process may further include bonding the device wafer to a carrier wafer. At block 1010, the process may include performing a TSV reveal. At block 1012, the process may include applying package side metallization and bumps. At block 1014, the process may further include bonding another carrier wafer, which may be a glass wafer, and performing a de-bond. At block 1016, the process may further include applying an SMA layer to the backside of the wafer, and then annealing all or part of the applied SMA layer. In embodiments, the SMA layer may be applied using a sputtering technique. At block 1018, the process may further include performing a backside metal process (BSM). It should be appreciated that at block 1018 of a stage in the manufacturing process and subsequent stages, the annealed SMA layer would be in place, and high temperature processing at the stages would have warpage mitigated.

At block 1020, the process may further include performing a de-bond and mounting. At block 1022, the process may further include performing a stack singulation, for example by sawing. At block 1024, the resulting singulated stacks may be attached to a substrate, for example through TCB. At block 1026, the process may further include performing the final package assembly.

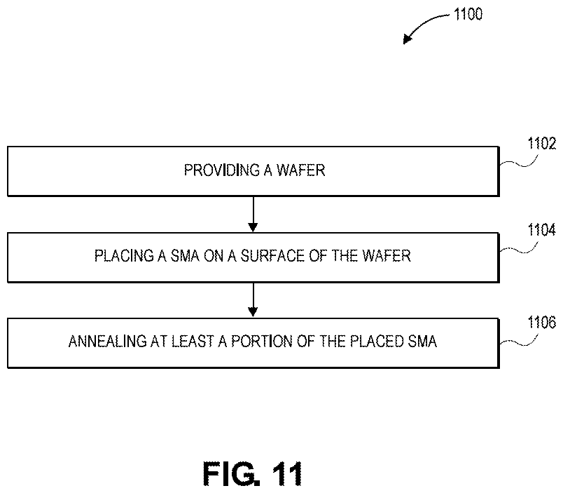

FIG. 11 illustrates an example of a process for forming an annealed SMA pattern on a surface of a base wafer, in accordance with various embodiments. Process 1100 may be performed using any of the techniques, processes, apparatus, and/or systems as described herein, and in particular with respect to FIGS. 1A-10.

At block 1102, the process may include providing a wafer. In embodiments, the wafer may be similar to base wafer 210 of FIGS. 2A-2D, base wafer 310 of FIGS. 3A-3D, wafer 450 of FIG. 4, or wafer 640 of FIG. 6.

At block 1104, the process may further include placing a SMA on a surface of the wafer. In embodiments, the SMA may be similar to SMA pattern 230 of FIGS. 2A-2D, SMA pattern 330 of FIGS. 3A-3D, SMA pattern 442, 444, 446, 448, 452, 454, 456, 458 of FIG. 4, or SMA layer 643 of FIG. 6.

At block 1106, the process may further include annealing at least a portion of the placed SMA. In embodiments, the annealing may be similar to the annealing process described with respect to FIG. 6, wherein a beam of light 662 from a laser 660 anneals a portion of the SMA layer 643 to produce the SMA pattern 642.

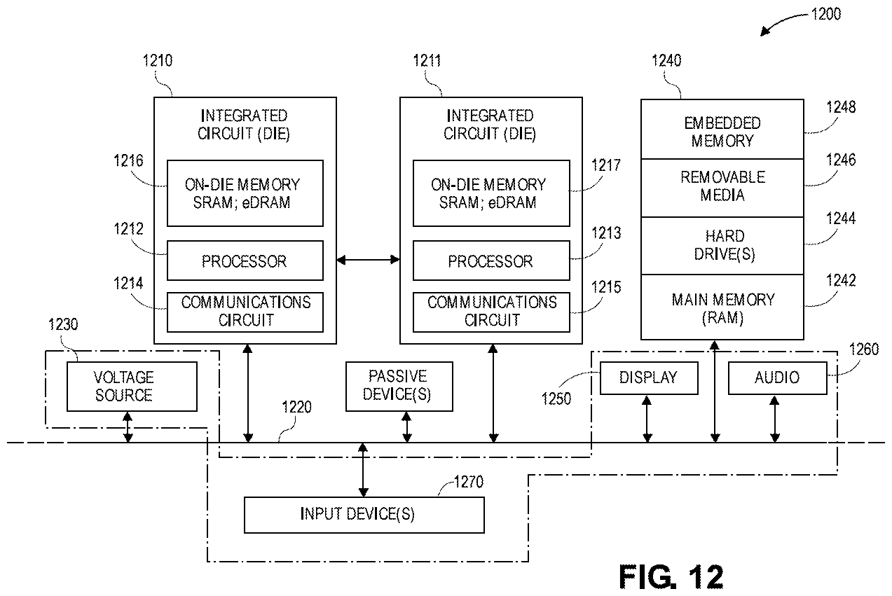

FIG. 12 is a schematic of a computer system 1200, in accordance with an embodiment of the present disclosure. The computer system 1200 (also referred to as the electronic system 1200) as depicted can embody annealed SMA on a substrate, according to any of the several disclosed embodiments and their equivalents as set forth in this disclosure. The computer system 1200 may be a mobile device such as a netbook computer. The computer system 1200 may be a mobile device such as a wireless smart phone. The computer system 1200 may be a desktop computer. The computer system 1200 may be a hand-held reader. The computer system 1200 may be a server system. The computer system 1200 may be a supercomputer or high-performance computing system.

In an embodiment, the electronic system 1200 is a computer system that includes a system bus 1220 to electrically couple the various components of the electronic system 1200. The system bus 1220 is a single bus or any combination of busses according to various embodiments. The electronic system 1200 includes a voltage source 1230 that provides power to the integrated circuit 1210. In some embodiments, the voltage source 1230 supplies current to the integrated circuit 1210 through the system bus 1220.

The integrated circuit 1210 is electrically coupled to the system bus 1220 and includes any circuit, or combination of circuits according to an embodiment. In an embodiment, the integrated circuit 1210 includes a processor 1212 that can be of any type. As used herein, the processor 1212 may mean any type of circuit such as, but not limited to, a microprocessor, a microcontroller, a graphics processor, a digital signal processor, or another processor. In an embodiment, the processor 1212 includes, or is coupled with, annealed SMA on a substrate, as disclosed herein. In an embodiment, SRAM embodiments are found in memory caches of the processor. Other types of circuits that can be included in the integrated circuit 1210 are a custom circuit or an application-specific integrated circuit (ASIC), such as a communications circuit 1214 for use in wireless devices such as cellular telephones, smart phones, pagers, portable computers, two-way radios, and similar electronic systems, or a communications circuit for servers. In an embodiment, the integrated circuit 1210 includes on-die memory 1216 such as static random-access memory (SRAM). In an embodiment, the integrated circuit 1210 includes embedded on-die memory 1216 such as embedded dynamic random-access memory (eDRAM).

In an embodiment, the integrated circuit 1210 is complemented with a subsequent integrated circuit 1211. Useful embodiments include a dual processor 1213 and a dual communications circuit 1215 and dual on-die memory 1217 such as SRAM. In an embodiment, the dual integrated circuit 1210 includes embedded on-die memory 1217 such as eDRAM.

In an embodiment, the electronic system 1200 also includes an external memory 1240 that in turn may include one or more memory elements suitable to the particular application, such as a main memory 1242 in the form of RAM, one or more hard drives 1244, and/or one or more drives that handle removable media 1246, such as diskettes, compact disks (CDs), digital variable disks (DVDs), flash memory drives, and other removable media known in the art. The external memory 1240 may also be embedded memory 1248 such as the first die in a die stack, according to an embodiment.

In an embodiment, the electronic system 1200 also includes a display device 1250, an audio output 1260. In an embodiment, the electronic system 1200 includes an input device such as a controller 1270 that may be a keyboard, mouse, trackball, game controller, microphone, voice-recognition device, or any other input device that inputs information into the electronic system 1200. In an embodiment, an input device 1270 is a camera. In an embodiment, an input device 1270 is a digital sound recorder. In an embodiment, an input device 1270 is a camera and a digital sound recorder.

As shown herein, the integrated circuit 1210 can be implemented in a number of different embodiments, including a package substrate having annealed SMA on a substrate, according to any of the several disclosed embodiments and their equivalents, an electronic system, a computer system, one or more methods of fabricating an integrated circuit, and one or more methods of fabricating an electronic assembly that includes a package substrate having annealed SMA on a substrate, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having annealed SMA on a substrate embodiments and their equivalents. A foundation substrate may be included, as represented by the dashed line of FIG. 12. Passive devices may also be included, as is also depicted in FIG. 12.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope is to be determined entirely by the following claims, which are to be construed in accordance with established doctrines of claim interpretation.

### EXAMPLES

The following paragraphs describe examples of various embodiments.

Example 1 is an apparatus comprising: a die; and a metal alloy on a surface of the die, wherein the metal alloy includes a selected one or more of: nickel and titanium; copper, aluminum, and nickel; iron, manganese and silicon; copper, zinc, and aluminum; silver and cadmium; gold and cadmium; copper, aluminum, and nickel; copper and tin; copper and zinc; indium and titanium; nickel and aluminum; iron and platinum; or manganese and copper.

Example 2 includes the apparatus of example 1, wherein the die is a silicon die.

Example 3 includes the apparatus of examples 1 or 2, wherein the metal alloy distributed in a pattern on the surface of the die.

Example 4 includes the apparatus of example 3, wherein the pattern includes a selected one or more of: a solid pattern, a one-axis pattern, a two-axis pattern, a radial pattern, or a concentric ring pattern.

Example 5 includes the apparatus of examples 3 or 4, wherein the pattern includes a first portion that includes the metal alloy proximate to one or more edges of the surface of the die and a second portion that includes no alloy proximate to a center of the surface of the die.

Example 6 includes the apparatus of examples 1, 2, 3, 4, or 5, further comprising a wafer, wherein the die is on a surface of the wafer.

Example 7 includes the apparatus of example 6, further comprising a mold compound on the surface of the wafer, wherein the mold compound at least partially surrounds the die.

Example 8 includes the apparatus of example 7, wherein the surface of the wafer is a first surface of the wafer, and further comprising a second surface of the wafer opposite the first surface of the wafer; and further comprising a die on the second surface of the wafer.

Example 9 includes the apparatus of example 8, further comprising a mold compound on the second surface of the wafer, wherein the mold compound at least partially surrounds the die on the second surface of the wafer.

Example 10 is a package comprising: a wafer; one or more dies on a surface of the wafer; a mold compound on the surface of the wafer, the mold compound surrounds at least a portion of the one or more dies; and a metal alloy on at least one of the one or more dies, wherein the metal alloy is a shape metal alloy (SMA).

Example 11 includes the package of example 10, wherein the SMA includes a selected one or more of: nickel and titanium; copper, aluminum, and nickel; iron, manganese and silicon; copper, zinc, and aluminum; silver and cadmium; gold and cadmium; copper, aluminum, and nickel; copper and tin; copper and zinc; indium and titanium; nickel and aluminum; iron and platinum; or manganese and copper.

Example 12 includes the package of examples 10 or 11, wherein the metal alloy on the one or more dies is distributed in a pattern.

Example 13 includes the package of examples 10, 11, or 12, wherein the metal alloy has a thickness that varies across the one or more dies.

Example 14 includes the package of examples 10, 11, 12, or 13, wherein the metal alloy has been annealed.

Example 15 includes the package of examples 10, 11, 12, 13, or 14, wherein the one or more dies are coupled with the wafer using a plurality of solder balls, and wherein at least a portion of the metal alloy is on the surface of the wafer and between two of the plurality of solder balls.

Example 16 includes the package of examples 10, 11, 12, 13, 14, or 15, wherein the wafer is a silicon base wafer.

Example 17 is a method comprising: providing a wafer; placing a shape metal alloy (SMA) on a surface of the wafer; and annealing at least a portion of the placed SMA.

Example 18 includes the method of example 17, wherein the SMA includes a selected one or more of: nickel and titanium; copper, aluminum, and nickel; iron, manganese and silicon; copper, zinc, and aluminum; silver and cadmium; gold and cadmium; copper, aluminum, and nickel; copper and tin; copper and zinc; indium and titanium; nickel and aluminum; iron and platinum; or manganese and copper.

Example 19 includes the method of example 18, wherein placing the SMA on the surface of the wafer further includes sputtering the SMA on the surface of the wafer, wherein annealing at least the portion of the placed SMA further includes annealing at least the portion of the placed SMA using a laser.

Example 20 includes the method of examples 17, 18, or 19, wherein placing the SMA on the surface of the wafer further includes placing the SMA on the surface of the wafer in a pattern that includes a selected one or more of: a solid pattern, a one-axis pattern, a two-axis pattern, a radial pattern, or a concentric ring pattern.

What is claimed is:

1. An apparatus comprising:
a die; and
a metal alloy on a surface of the die, wherein the metal alloy includes a selected one or more of: nickel and titanium; copper, aluminum, and nickel; iron, manganese and silicon; copper, zinc, and aluminum; silver and cadmium; gold and cadmium; copper, aluminum, and nickel; copper and tin; copper and zinc; indium and titanium; nickel and aluminum; iron and platinum; or manganese and copper.

2. The apparatus of claim 1, wherein the die is a silicon die.

3. The apparatus of claim 1, wherein the metal alloy distributed in a pattern on the surface of the die.

4. The apparatus of claim 3, wherein the pattern includes a selected one or more of: a solid pattern, a one-axis pattern, a two-axis pattern, a radial pattern, or a concentric ring pattern.

5. The apparatus of claim 3, wherein the pattern includes a first portion that includes the metal alloy proximate to one or more edges of the surface of the die and a second portion that includes no alloy proximate to a center of the surface of the die.

6. The apparatus of claim 1, further comprising a wafer, wherein the die is on a surface of the wafer.

7. The apparatus of claim 6, further comprising a mold compound on the surface of the wafer, wherein the mold compound at least partially surrounds the die.

8. The apparatus of claim 7, wherein the surface of the wafer is a first surface of the wafer, and further comprising a second surface of the wafer opposite the first surface of the wafer; and further comprising a die on the second surface of the wafer.

9. The apparatus of claim 8, further comprising a mold compound on the second surface of the wafer, wherein the mold compound at least partially surrounds the die on the second surface of the wafer.

10. A package comprising:
a wafer;
one or more dies on a surface of the wafer;
a mold compound on the surface of the wafer, the mold compound surrounds at least a portion of the one or more dies; and
a metal alloy on at least one of the one or more dies, wherein the metal alloy is a shape metal alloy (SMA).

11. The package of claim 10, wherein the SMA includes a selected one or more of: nickel and titanium; copper, aluminum, and nickel; iron, manganese and silicon; copper, zinc, and aluminum; silver and cadmium; gold and cadmium; copper, aluminum, and nickel; copper and tin; copper and zinc; indium and titanium; nickel and aluminum; iron and platinum; or manganese and copper.

12. The package of claim 10, wherein the metal alloy on the one or more dies is distributed in a pattern.

13. The package of claim 10, wherein the metal alloy has a thickness that varies across the one or more dies.

14. The package of claim 10, wherein the metal alloy has been annealed.

15. The package of claim 10, wherein the one or more dies are coupled with the wafer using a plurality of solder balls, and wherein at least a portion of the metal alloy is on the surface of the wafer and between two of the plurality of solder balls.

16. The package of claim 10, wherein the wafer is a silicon base wafer.

17. A method comprising:
providing a wafer;
placing a shape metal alloy (SMA) on a surface of the wafer; and
annealing at least a portion of the placed SMA.

18. The method of claim 17, wherein the SMA includes a selected one or more of: nickel and titanium; copper, aluminum, and nickel; iron, manganese and silicon; copper, zinc, and aluminum; silver and cadmium; gold and cadmium; copper, aluminum, and nickel; copper and tin; copper and zinc; indium and titanium; nickel and aluminum; iron and platinum; or manganese and copper.

19. The method of claim 18, wherein placing the SMA on the surface of the wafer further includes sputtering the SMA on the surface of the wafer, wherein annealing at least the portion of the placed SMA further includes annealing at least the portion of the placed SMA using a laser.

20. The method of claim 17, wherein placing the SMA on the surface of the wafer further includes placing the SMA on the surface of the wafer in a pattern that includes a selected one or more of: a solid pattern, a one-axis pattern, a two-axis pattern, a radial pattern, or a concentric ring pattern.
